(19) United States
(12) Patent Application Publication
(10) Pub. No.: US 2025/0294756 A1
(43) Pub. Date: Sep. 18, 2025

(54) SEMICONDUCTOR MEMORY DEVICE

(71) Applicant: Kioxia Corporation, Tokyo (JP)

(72) Inventors: Kohei YOSHIMI, Yokkaichi Mie (JP); Kazuharu YAMABE, Yokkaichi Mie (JP)

(21) Appl. No.: 19/061,584

(22) Filed: Feb. 24, 2025

(30) Foreign Application Priority Data
Mar. 18, 2024 (JP) 2024-042717

(51) Int. Cl. H10B 43/27; H10B 41/27

(52) U.S. Cl. CPC H10B 43/27; H10B 41/27

(57) ABSTRACT

A semiconductor memory device includes a stacked body including first conductive layers and insulating layers alternately stacked in a first direction; a second conductive layer disposed outside the stacked body; a third conductive layer surrounding the stacked body; a first wiring layer provided above the stacked body and extending in a second direction; a second wiring layer provided above the stacked body and provided apart from the first wiring layer; an electrode layer provided above the first wiring layer and the second wiring layer, and connected to each of upper portions of the second conductive layer and the third conductive layer; and a pad portion provided in the electrode layer. A first region, including the first wiring layer, the pad portion, and the second conductive layer, and a second region, including the second wiring layer and the third conductive layer, are adjacent to each other in the second direction.

### CROSS-REFERENCE TO RELATED APPLICATIONS

This application is based upon and claims the benefit of priority from Japanese Patent Application No. 2024-042717, filed Mar. 18, 2024, the entire contents of which are incorporated herein by reference.

### FIELD

Embodiments described herein relate generally to a semiconductor memory device.

### BACKGROUND

In a semiconductor memory device, an edge seal may be disposed outside an element region in order to protect an element. The insulating layer fills the periphery of the element region and the edge seal. Above the insulating layer, a source line connected to the element, and an electrode layer penetrating between the source lines and connected to each of the element and the edge seal, are disposed. The electrode layer connected to the element and the electrode layer connected to the edge seal are electrically separated from each other.

However, the source line between the electrode layers may be deformed by various types of heat processing in the manufacturing step of the semiconductor memory device. When the source line is deformed, the electrode layer may be formed poorly, and a short circuit may occur between the electrode layers that are electrically separated from each other.

### DESCRIPTION OF THE DRAWINGS

FIGS. 1A and 1B are cross-sectional views showing a schematic configuration example of a semiconductor memory device according to an embodiment.

FIGS. 2A to 2C are views showing a positional relationship of each configuration in a peripheral region and an outer peripheral region according to the embodiment.

FIGS. 3A to 3C are views sequentially showing a part of the procedure of a method for manufacturing a semiconductor memory device according to the embodiment.

FIGS. 4A and 4B are views sequentially showing a part of the procedure of the method for manufacturing the semiconductor memory device according to the embodiment.

FIGS. 5A and 5B are views sequentially showing a part of the procedure of the method for manufacturing the semiconductor memory device according to the embodiment.

FIGS. 6A and 6B are views sequentially showing a part of the procedure of the method for manufacturing the semiconductor memory device according to the embodiment.

FIGS. 7A and 7B are views sequentially showing a part of the procedure of the method for manufacturing the semiconductor memory device according to the embodiment.

FIGS. 8A and 8B are views sequentially showing a part of the procedure of the method for manufacturing the semiconductor memory device according to the embodiment.

FIGS. 9A and 9B are views sequentially showing a part of the procedure of the method for manufacturing the semiconductor memory device according to the embodiment.

FIGS. 10A and 10B are views sequentially showing a part of the procedure of the method for manufacturing the semiconductor memory device according to the embodiment.

FIGS. 11A and 11B are views sequentially showing a part for manufacturing the of the procedure of the method semiconductor memory device according to the embodiment.

FIGS. 12A and 12B are views sequentially showing a part of the procedure of the method for manufacturing the semiconductor memory device according to the embodiment.

FIG. 13 is a view sequentially showing a part of the procedure of the method for manufacturing the semiconductor memory device according to the embodiment.

FIGS. 14A to 14C are diagrams showing a semiconductor memory device according to a comparative example.

FIGS. 15A to 15C are views showing a semiconductor memory device according to a comparative example.

### DETAILED DESCRIPTION

Embodiments provide a semiconductor memory device capable of reducing a short circuit between electrode layers.

In general, according to one embodiment, a semiconductor memory device includes: a stacked body including a plurality of first conductive layers and a plurality of insulating layers alternately stacked in a first direction; a second conductive layer extending in the first direction and disposed outside the stacked body; a third conductive layer extending in the first direction and surrounding the stacked body when viewed in the first direction; a first wiring layer provided above the stacked body and extending in a second direction that intersects the first direction; a second wiring layer provided above the stacked body and provided apart from the first wiring layer in the second direction; an electrode layer provided above the first wiring layer and the second wiring layer, and connected to each of upper portions of the second conductive layer and the third conductive layer between the first wiring layer and the second wiring layer; and a pad portion provided in the electrode layer and configured to supply external power to the second conductive layer and the third conductive layer via the electrode layer. A first region, including the first wiring layer, the pad portion, and the second conductive layer, and a second region, including the second wiring layer and the third conductive layer, are adjacent to each other in the second direction.

Hereinafter, embodiments will be described in detail with reference to the drawings. Further, the present disclosure is not limited to the following embodiment. The elements in the following embodiments include those that can be easily assumed by those skilled in the art or those that are substantially the same.

### Configuration Example of Semiconductor Memory Device

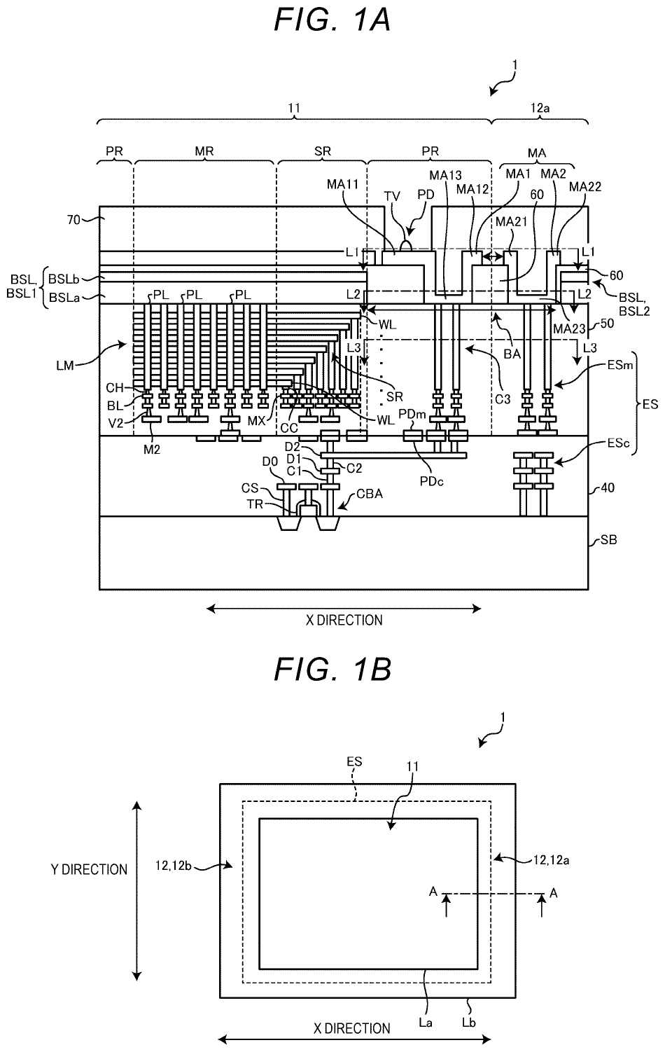

FIGS. 1A and 1B are views showing a schematic configuration example of a semiconductor memory device 1 according to an embodiment. Specifically, FIG. 1A is a cross-sectional view taken along an X direction of the semiconductor memory device 1, and FIG. 1B is a top view schematically showing the semiconductor memory device 1. FIG. 1A is also a cross-sectional view taken along line A-A of FIG. 1B. However, in FIG. 1A, hatching is omitted for the sake of the clarity of the drawing. In addition, in FIG. 1B, for convenience of description, a configuration that may not always be visually recognized when viewed from above is also shown, such as an edge seal ES.

In the present specification, both the X direction and the Y direction are directions along the orientations of the surfaces of the plurality of word lines WL to be described later, and the X direction and the Y direction are orthogonal to each other. The X direction and the Y direction are directions that intersect a stacking direction of the plurality of word lines WL. The stacking direction of the plurality of word lines WL is an example of a first direction, and an X direction is an example of a second direction.

As shown in FIG. 1A, the semiconductor memory device 1 includes a peripheral circuit CBA, the plurality of word lines WL, a source-side wiring layer BSL, and an electrode layer MA in this order above a semiconductor substrate SB. The side where the semiconductor substrate SB is disposed is defined as the lower side of the semiconductor memory device 1.

The semiconductor substrate SB is, for example, a silicon substrate, and the like. A peripheral circuit CBA including a plurality of transistors TR and the like is disposed on the semiconductor substrate SB. The peripheral circuit CBA contributes to the operation of the memory cell to be described later.

The peripheral circuit CBA is covered with an insulating layer 40. An edge seal ESc that extends from the semiconductor substrate SB side to the surface side of the insulating layer 40 through the insulating layer 40 is disposed in the insulating layer 40 around the peripheral circuit CBA. In addition, the plurality of word lines WL are stacked above the insulating layer 40.

The plurality of word lines WL are alternately stacked with the plurality of insulating layers one by one to form a stacked body LM. The word line WL is an example of a first conductive layer. Each of the plurality of insulating layers is an example of a first insulating layer. The plurality of word lines WL are covered with an insulating layer 50 and are bonded to the insulating layer 40 that covers the peripheral circuit CBA via the insulating layer 50. The insulating layer 50 also widens around the plurality of word lines WL. The memory region MR is disposed in the plurality of word lines WL, and the staircase region SR is disposed at the end portions of the plurality of word lines WL.

Although not shown, in the plurality of word lines WL, a plurality of plate-shaped contacts that penetrate the word lines WL in the stacking direction and extend in the direction along the X direction are disposed. The plurality of word lines WL are divided in the Y direction by a plurality of plate-shaped contacts. The insulating layer 50 covering the plurality of word lines WL is also divided in the Y direction by a plurality of plate-shaped contacts. A plurality of memory regions MR, the staircase region SR, and a peripheral region PR to be described later are disposed between the plurality of plate-shaped contacts in the X direction.

In the memory region MR, pillars PL as a plurality of semiconductor layers that penetrate the stacked body LM in a stacking direction as a first direction, are disposed. A memory cell as a memory layer part is formed at an intersection portion between the pillar PL and the word line WL. Thereby, the semiconductor memory device 1 is configured as, for example, a three-dimensional non-volatile memory in which the memory cells are disposed in three dimensions in the memory region MR.

In the staircase region SR, an end portion of the stacked body LM is processed into a stepped shape. As a result, the end portions of the plurality of word lines WL widen toward the outside of the plurality of word lines WL as the end portions go upward. Contacts CC are respectively connected to each layer of the plurality of word lines WL in a stepped shape.

The word lines WL, which are stacked in multiple layers, are individually drawn out by these contacts CC. From these contacts CC, write voltage, read voltage, and the like are applied to the memory cells provided in the memory region MR at the central portion of the plurality of word lines WL via the word lines WL having the same height position as the memory cells. Various voltages applied from the contact CC to the memory cell are controlled by the peripheral circuit CBA electrically connected to these contacts CC.

A region outside the staircase region SR is a peripheral region PR. The contact C3 is disposed in the peripheral region PR. The contact C3 extends in the stacking direction of the plurality of word lines WL in the insulating layer 50. The contact C3 is electrically connected to an electrode layer MA to be described later at the upper surface and to the peripheral circuit CBA at the lower end portion via a plug V0 or the like to be described later. The external power applied to the electrode layer MA is supplied to the peripheral circuit CBA via the contact C3. The contact C3 is an example of a second conductive layer.

The memory region MR, the staircase region SR, and the peripheral region PR described above constitute a part of an element region 11 shown in FIG. 1B. A frame line La shown in FIG. 1B indicates an outermost periphery of the element region 11, and a frame line Lb indicates an outermost periphery of the semiconductor memory device 1. The region outside the element region 11, that is, the region between the frame line La and the frame line Lb is an outer peripheral region 12. That is, the element region 11 and the outer peripheral region 12 are adjacent to each other via the frame line La. The element region 11 is an example of a first region, and the outer peripheral region 12 is an example of a second region.

More specifically, in FIG. 1B, when a side of the outer peripheral region 12 indicated by line A-A is referred to as an outer peripheral region 12a, the edge seal ES that extends in the Y direction is disposed in the outer peripheral region 12a. In addition, when a part of the outer peripheral region 12 facing the outer peripheral region 12a in the X direction via the element region 11 is referred to as an outer peripheral region 12b, the edge seal ES as a fourth conductive layer that extends along the Y direction is also disposed in the outer peripheral region 12b. The outer peripheral region 12b is an example of a fourth region. The edge seal ES is also an example of a third conductive layer.

The edge seal ES includes an edge seal ESm that extends in the stacked body direction in the insulating layer 50, and the edge seal ESc that extends in the insulating layer 40 described above. The edge seal ESm is an example of a third conductive layer. The third conductive layer may include the edge seal ESc.

The edge seal ESm is disposed at a position that surrounds the stacked body LM and the wiring or the like associated with the stacked body LM when viewed in the stacking direction. The edge seal ESm is connected to the electrode layer MA to be described later on the upper surface. That is, the edge seal ESm is disposed over the entire height position of the pillars PL, the contacts CC, a plurality of plugs CH and V2 connected to the lower end portions of the pillars PL and the contacts CC, bit lines BL, and the wiring layers MX and M2 in the insulating layer 50.

The edge seal ESc is disposed at a position overlapping the edge seal ESm described above in the up-and-down direction, and surrounds the peripheral circuit CBA. That is, the edge seal ESc is disposed over the entire height position of the plurality of wiring layers D0, D1, and D2, and the contacts CS and vias C1 and C2 in the insulating layer 40. The edge seal ESc may be connected to the edge seal ESm via each wiring layer.

The edge seal ES is adjusted to a predetermined potential by the external power supplied from the electrode layer MA. Thereby, the element region 11 surrounded by the edge seal ES is electrically shielded from the outside. In addition, the edge seal ES can prevent the impurities from being mixed into the element region 11 from the outside by being a physical shielding structure. In addition, the edge seal ES prevents the element region 11 from being cracked, chipped, and the like when the semiconductor memory device 1 is individually divided by dicing or the like in the final stage of the manufacturing step.

The source-side wiring layer BSL and an insulating layer 60 made of silicon oxide or the like are formed in this order on the insulating layer 50. The source-side wiring layer BSL is connected to the upper surfaces of the plurality of pillars PL in the memory region MR and functions as a source line of the memory cell. In addition, the source-side wiring layer BSL is provided on the upper surface of the insulating layer 50.

As described above, the insulating layer 50 is divided in the Y direction by a plurality of plate-shaped contacts that extends in the direction along the X direction. Therefore, the source-side wiring layer BSL also extends in the direction along the X direction and is divided in the Y direction.

In addition, the source-side wiring layer BSL is also divided in the X direction. Specifically, the source-side wiring layer BSL includes a source-side wiring layer BSL1 and a source-side wiring layer BSL2 provided on the upper surface of the insulating layer 50 at positions apart from each other in the X direction. More specifically, as shown in FIG. 1A, the source-side wiring layer BSL is divided into the element region 11 side and the outer peripheral region 12a side by not being formed in a region BA on the upper surface of the insulating layer 50. The source-side wiring layer BSL provided on the element region 11 side is a source-side wiring layer BSL1 as a first wiring layer, and the source-side wiring layer BSL provided on the outer peripheral region 12a side is a source-side wiring layer BSL2 as a second wiring layer.

A region BA is provided between the source-side wiring layer BSL1 and the source-side wiring layer BSL2. The region BA at least separates the element region 11 from the outer peripheral region 12a. A detailed configuration of the region BA will be described later.

The source-side wiring layer BSL has a stacked structure in which a source line layer BSLa and an insulating layer BSLb are stacked in this order from below. The source line layer BSLa is, for example, a conductive polysilicon layer in which impurities are diffused, and the insulating layer BSLb is, for example, a silicon oxide layer.

The electrode layer MA is disposed on the insulating layer 60. The electrode layer MA is provided above the source-side wiring layer BSL, penetrates the insulating layer 60 in the stacking direction in the region BA between the source-side wiring layer BSL1 and the source-side wiring layer BSL2, and is connected to the upper portion of the contact C3 and the edge seal ESm. Thereby, the electrode layer MA can supply the applied external power to the contact C3 and the edge seal ESm. The electrode layer MA is, for example, an aluminum layer.

Specifically, the electrode layer MA includes an electrode layer MA1 connected to the contact C3 and an electrode layer MA2 connected to the edge seal ESm, and the electrode layer MA1 is configured to have a pad portion PD.

The electrode layer MA1 and the electrode layer MA2 are electrically separated from each other. The electrode layer MA1 is provided generally in the peripheral region PR and is connected to the contact C3. The electrode layer MA2 is provided generally in the outer peripheral region 12a and is connected to the edge seal ESm. Thereby, the contact C3 disposed in the peripheral region PR and the edge seal ESm disposed in the outer peripheral region 12a are electrically separated from each other. The electrode layer MA1 is an example of a first electrode layer, and the electrode layer MA2 is an example of a second electrode layer.

Specifically, the electrode layer MAL is configured to have an electrode portion MA11 as a first portion, an electrode portion MA12 as a second portion, and an electrode portion MA13 as a third portion. The electrode portion MA11 and the electrode portion MA12 are parts provided above the source-side wiring layer BSL1. The electrode portion MA13 is a part positioned below the electrode portion MA11 and the electrode portion MA12 and connected to the contact C3. The electrode portion MA11 is also a pad portion PD.

In addition, the electrode layer MA2 is configured to have an electrode portion MA21 as a fourth portion, an electrode portion MA22 as a fifth portion, and an electrode portion MA23 as a sixth portion. The electrode portion MA21 and the electrode portion MA22 are parts provided above the source-side wiring layer BSL2. The electrode portion MA23 is a part positioned below the electrode portion MA21 and the electrode portion MA22 and is connected to the edge seal ESm.

The electrode portions MA13 and MA23 are positioned above the word line WL positioned at an uppermost position of the word lines WL. In addition, the insulating layer 60 as a second insulating layer is provided between the electrode portion MA12 and the electrode portion MA21.

The electrode layer MA is covered with an insulating layer 70 made of polyimide or the like except for the pad portion PD. A bonding TV is provided on the pad portion PD. The bonding TV supplies external power to the contact C3 via the electrode layer MA.

Although FIG. 1A shows an example in which the pad portion PD is provided on the electrode layer MA1 and the external power is supplied to the contact C3 via the electrode layer MA1, the present disclosure is not limited thereto. The electrode layers MA1 and MA2 are provided with a plurality of pad portions, and some of the plurality of pad portions supply external power to the edge seal ESm via the electrode layer MA2.

A plurality of wiring layers for electrically connecting various configurations on the stacked body LM side to the peripheral circuit CBA are disposed in the insulating layers 40 and 50 between the peripheral circuit CBA and the stacked body LM. The plurality of wiring layers as metal wiring layers are provided below the stacked body LM and are disposed at a position overlapping the stacked body LM in the stacking direction.

For example, below the stacked body LM in the insulating layer 50, the plug V0, the wiring layer M0, the plug V1, the wiring layer M1, the plug V2, the wiring layer M2, and the like are disposed in order from the word line WL side toward the surface side of the insulating layer 50, and various components on the word line WL side are electrically connected to an electrode pad PDm disposed on the surface of the insulating layer 50. In addition, the insulating layer 50 includes the plug CH disposed in the same layer as the plug V0, the wiring layer MX disposed in the same layer as the wiring layer M0, the bit line BL, and the like. The plug V0, the wiring layer M0, the plug V1, the wiring layer M1, the plug V2, the wiring layer M2, and the electrode pad PDm, which are described above, are examples of a metal wiring layer.

For example, in the insulating layer 40 below the insulating layer 50, the contact CS, the wiring layer D0, the via C1, the wiring layer D1, the via C2, the wiring layer D2, and the like are disposed in order from the transistor TR side of the peripheral circuit CBA toward the surface side of the insulating layer 40, and the transistors TR and the like are electrically connected to an electrode pad PDc disposed on the surface of the insulating layer 40. The electrode pad PDc is connected to the electrode pad DPm on the surface of the insulating layer 50 described above. Thereby, the plug, the wiring layer, and the like on the word line WL side described above are electrically connected to the peripheral circuit CBA.

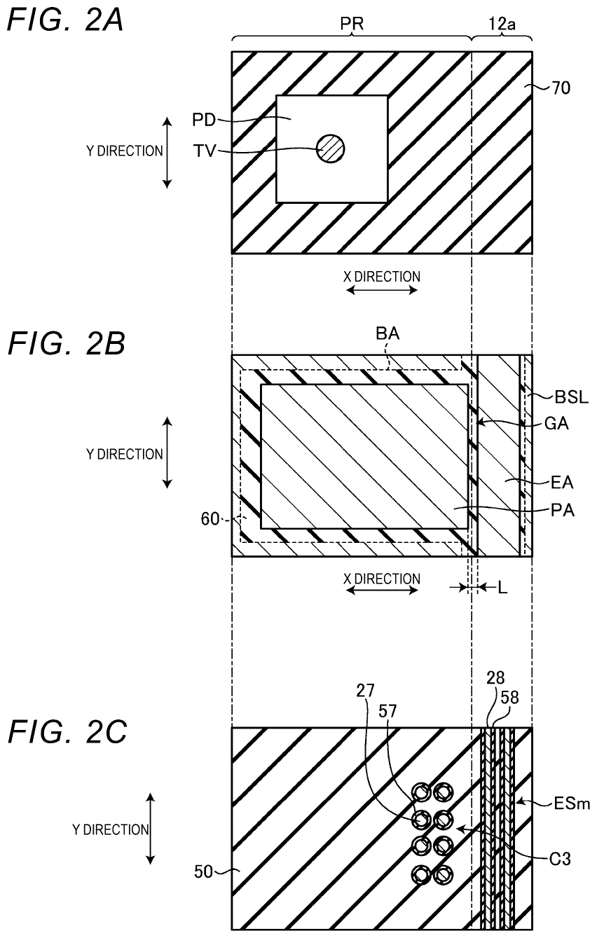

Here, the configuration example of the peripheral region PR and the outer peripheral region 12a will be described in detail with reference to FIG. 2.

FIGS. 2A to 2C are views showing a positional relationship of each configuration in the peripheral region PR and the outer peripheral region 12a according to the embodiment. More specifically, FIG. 2A is an XY cross-sectional view taken along line L1-L1 of FIG. 1A, FIG. 2B is an XY cross-sectional view taken along line L2-L2 of FIG. 1A, and FIG. 2C is an XY cross-sectional view taken along line L3-L3 of FIG. 1A. In FIG. 2B, for convenience of description, t is assumed that a configuration in which a part of the electrode layer MA is not necessarily visually recognizable when viewed in cross section along line L2-L2 is also shown.

As shown in FIG. 2A, the upper surface of the semiconductor memory device 1 is covered with the insulating layer 70 except for the pad portion PD. The pad portion PD is formed in a substantially rectangular shape when viewed in the stacking direction, and has the bonding TV at a substantially central part.

As shown in FIG. 2B, the region BA is provided in a pad region PA including the pad portion PD provided in the peripheral region PR, an edge seal region EA including the edge seal ES provided in the outer peripheral region 12a, and a boundary part provided between the peripheral region PR and the outer peripheral region 12a. The source-side wiring layer BSL is dispersed in a region excluding the region BA. That is, the peripheral region PR and the outer peripheral region 12a are adjacent to each other without the source-side wiring layer BSL interposed therebetween.

A width L of a gap GA provided between the pad region PA and the edge seal region EA in the X direction is, for example, 2 μm or less.

As shown in FIG. 2C, the contact C3 is disposed at a position overlapping the pad region PA in the stacking direction, and has an insulating layer 57 that covers the outer periphery of the contact C3 and a conductive layer 27 such as a tungsten layer that fills the inside the insulating layer 57. Thereby, the contact C3 can supply the external power supplied from the electrode layer MA1 to the peripheral circuit CBA.

In addition, the edge seal ESm has an insulating layer 58 that covers the side wall of the edge seal ESm, and a conductive layer 28 such as a tungsten layer that fills the inside of the insulating layer 58. Thereby, the edge seal ESm can receive the supply of the external power from the electrode layer MA2.

### Method for Manufacturing of Semiconductor Memory Device

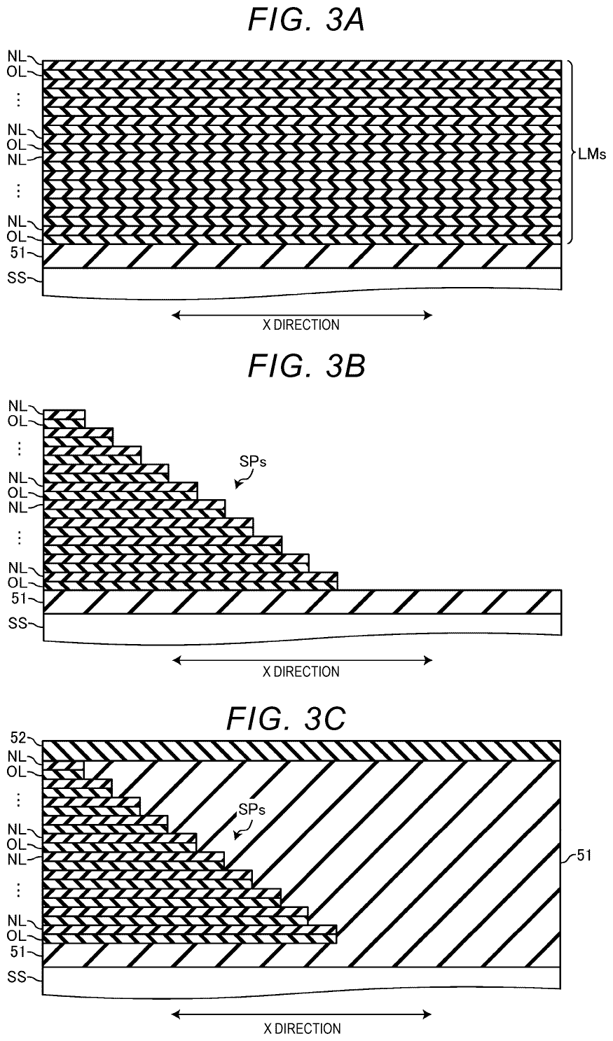

Next, a method for manufacturing the semiconductor memory device 1 according to the embodiment will be described with reference to FIGS. 3A to 13.

FIGS. 3A to 13 are views sequentially showing a part of a procedure of the method for manufacturing the semiconductor memory device 1 according to the embodiment. In each of FIGS. 3A to 13, the processing surface of the semiconductor memory device 1 in each step is shown facing upward on the paper surface. In addition, in the following description of the method for manufacturing the semiconductor memory device 1, for convenience of description, a direction in which a processing surface in each step faces is defined as an upper side.

First, a state where a part that becomes a step portion SP having a stepped shape disposed in the staircase region SR later is formed is shown in FIGS. 3A to 3C. FIGS. 3A to 3C show cross sections of the staircase region SR and the peripheral region PR during manufacturing along the X direction.

As shown in FIG. 3A, an insulating layer 51 is formed on a supporting substrate SS such as a silicon substrate.

In addition, a stacked body LMs in which a plurality of insulating layers NL and a plurality of insulating layers OL are alternately stacked one by one is formed on the insulating layer 51. The insulating layer NL is, for example, a silicon nitride layer or the like, and functions as a sacrificial layer to be replaced with the word line WL later.

A mask pattern (not shown) that covers a part of the stacked body LMs is formed on the stacked body LMs. The insulating layer NL and the insulating layer OL of the stacked body LMs are etched using a mask pattern. Next, the mask pattern is recessed by slimming using oxygen plasma or the like, and the insulating layer NL and the insulating layer OL of the newly exposed stacked body LMs are etched.

In this manner, the slimming of the mask pattern and the etching of the insulating layer NL and the insulating layer OL of the stacked body LMs are repeated a plurality of times.

Thereby, as shown in FIG. 3B, a step portion SPs that becomes the step portion SP later is formed. After the step portion SPs is formed, the mask pattern is removed by ashing using oxygen plasma or the like.

Next, as shown in FIG. 3C, the insulating layer 51 is stacked to cover the step portion SPs and to reach a height position of the upper surface of the unprocessed stacked body LMs. In addition, the upper surface of the unprocessed stacked body LMs and an insulating layer 52 that covers the insulating layer 51 of the step portion SPs are formed.

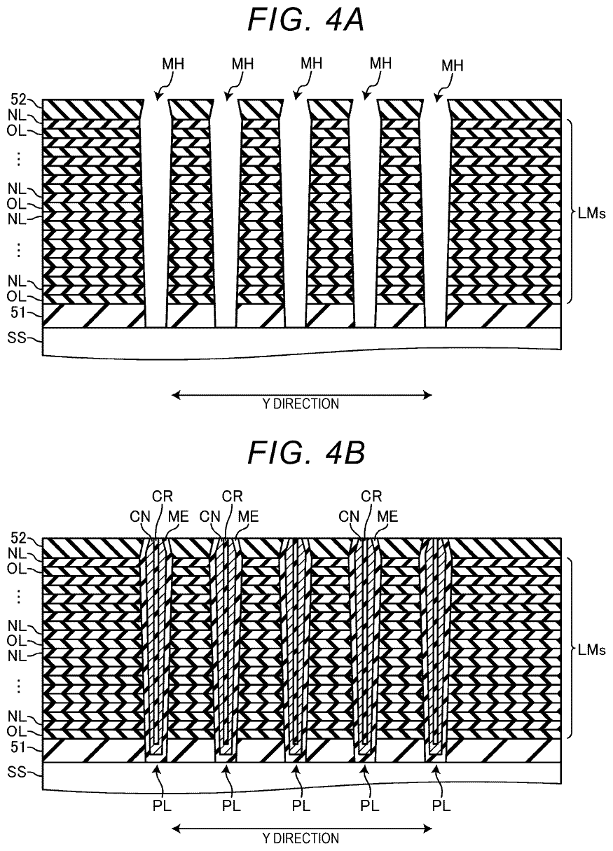

Next, a state where the pillar PL is formed is shown in FIGS. 4A and 4B. FIGS. 4A and 4B show cross sections of the memory region MR during manufacturing along the Y direction.

As shown in FIG. 4A, the insulating layer 51, the stacked body LMs, and the insulating layer 52 are formed in this order on the supporting substrate SS of the region that becomes the memory region MR later by the processing shown in FIGS. 3A to 3C described above. Next, a plurality of memory holes MH that penetrate the insulating layer 52, the stacked body LMs, and the insulating layer 51 and reach the supporting substrate SS, are formed.

As shown in FIG. 4B, a channel layer CN such as a polysilicon layer or an amorphous silicon layer is formed on the side wall and the bottom surface of the memory hole MH as a semiconductor layer via a memory layer ME. In addition, a core layer CR such as a silicon oxide layer fills the void of the memory hole MH remaining on the inner side of the channel layer CN. As described above, the plurality of pillars PL are formed.

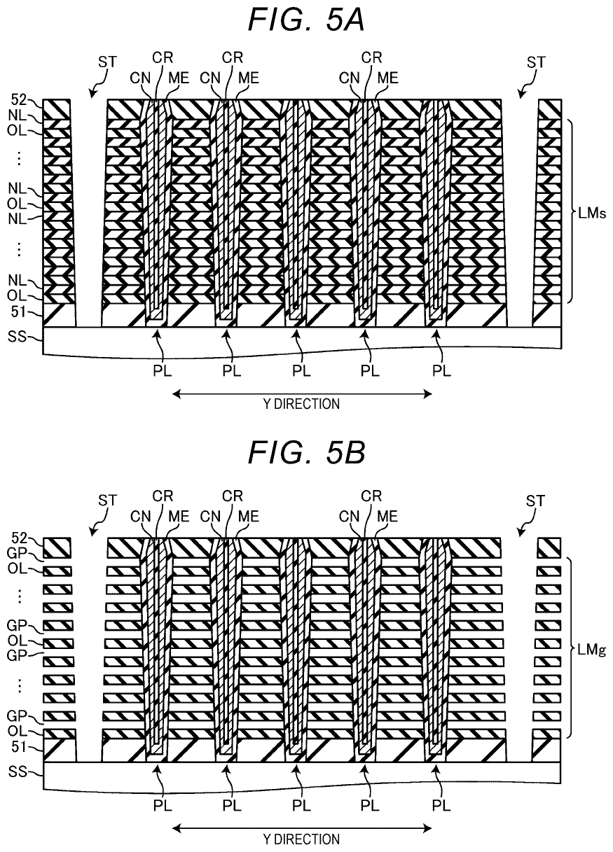

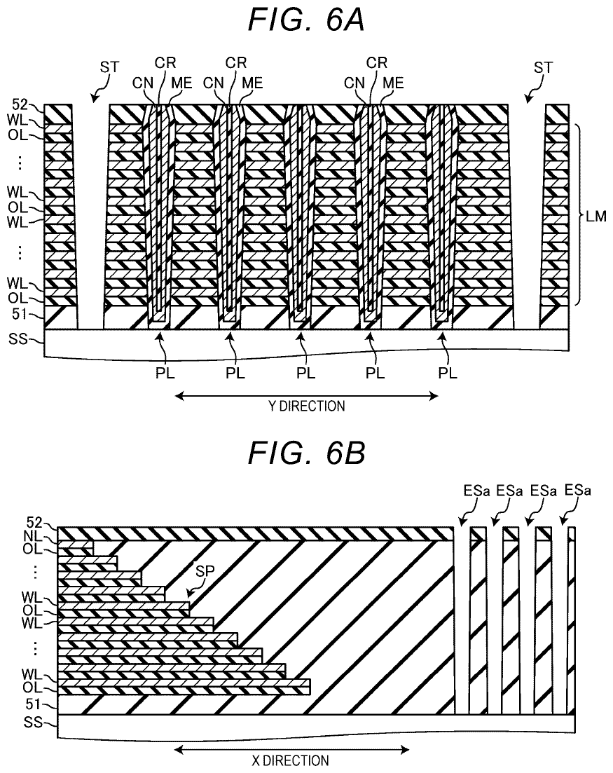

Next, a state where the word line WL is formed is shown in FIGS. 5A to 6B. FIGS. 5A to 6A show a cross section of the memory region MR during manufacturing along the Y direction, and FIG. 6B shows a cross section of the staircase region SR, the peripheral region PR, and the outer peripheral region 12a during manufacturing along the X direction.

As shown in FIG. 5A, a plurality of slits ST that penetrate the insulating layer 52, the stacked body LMs, and the insulating layer 51, and reach the supporting substrate SS, are formed. The plurality of slits ST also extend in the direction along the X direction in the stacked body LMs.

As shown in FIG. 5B, a remover for the insulating layer NL, such as hot phosphoric acid, is caused to flow into the inside of the stacked body LMs from the slit ST penetrating the stacked body LMs, thereby removing the insulating layer NL of the stacked body LMs. Thereby, a stacked body LMg having a plurality of gap layers GP from which the insulating layer NL between the insulating layers OL is removed is formed.

As shown in FIG. 6A, a raw gas of a conductive material such as tungsten or molybdenum is injected into the inside of the stacked body LMg from the slit ST, and the gap layer GP of the stacked body LMg is filled with the conductive material to form a plurality of word lines WL. Thereby, the stacked body LM in which the plurality of word lines WL and the plurality of insulating layers OL are alternately stacked one by one is formed.

At this time, by the processing shown in FIG. 5A described above, as shown in FIG. 6B, a plurality of slits ESa that penetrate the insulating layer 52 and the insulating layer 51 in the outer peripheral region 12a during manufacturing, and reach the supporting substrate SS, are formed.

In addition, by the processing shown in FIG. 5B described above, as shown in FIG. 6B, the insulating layer NL is also replaced with the word line WL in the staircase region SR during manufacturing, and the step portion SP in which the plurality of word lines WL are processed in a stepped shape is formed.

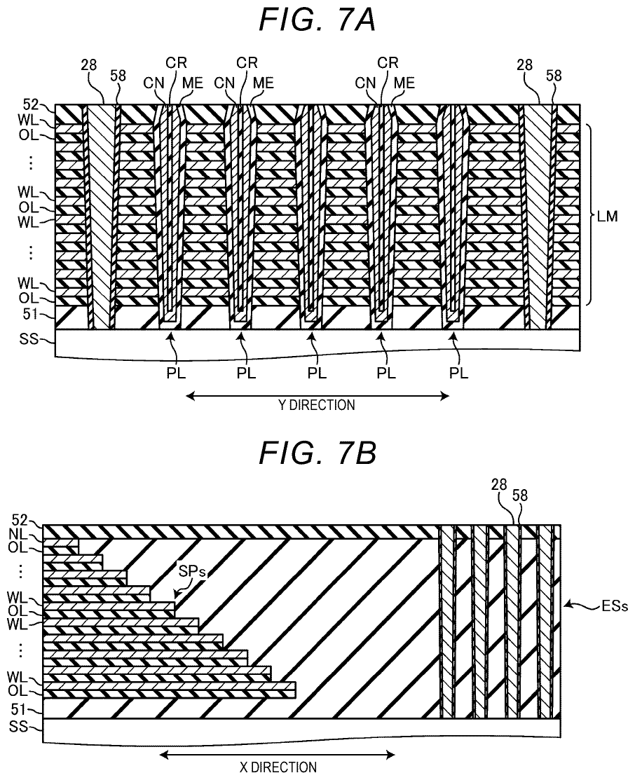

Next, a state where the plate-shaped contact L1 and the edge seal ESm are formed is shown in FIGS. 7A and 7B. FIG. 7A shows a cross section of the memory region MR during manufacturing along the Y direction. FIG. 7B shows a cross section of the staircase region SR, the peripheral region PR, and the outer peripheral region 12a during manufacturing along the X direction.

The insulating layer 58 is formed on the side walls of the slit ST and the slit ESa, and the conductive layer 28 fills the insulating layer 58 to form the plate-shaped contact LI that becomes a source line contact and an edge seal ESs which is a part of the edge seal ESm, respectively, as shown in FIGS. 7A and 7B. At this time, an unfilled part may be generated in the conductive layer 28 that fills the slits ST and ESa, and a void may be formed in the plate-shaped contact LI or the edge seal ESs.

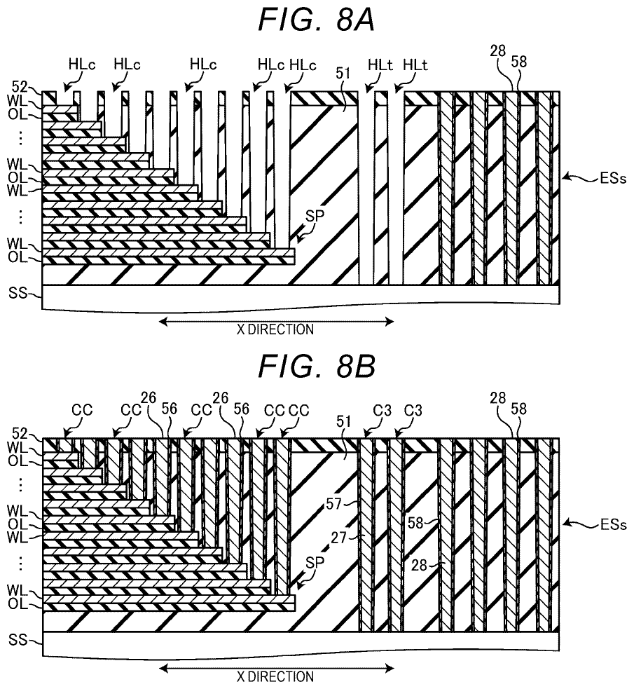

Next, a state where the contact CC and the contact C3 are formed is shown in FIGS. 8A and 8B. FIGS. 8A and 8B show cross sections of the staircase region SR, the peripheral region PR, and the outer peripheral region 12a during manufacturing along the X direction.

As shown in FIG. 8A, a plurality of contact holes HLc that penetrate the insulating layers 52 and 51 and reach the upper surfaces of the individual word lines WL processed in a stepped shape are formed. The contact hole HLc has a configuration that becomes the contact CC connected to the word line WL later.

In parallel with the formation of the contact holes HLc, contact holes HLt that penetrate the insulating layers 52 and 51 and reach the supporting substrate SS are formed in the region corresponding to the peripheral region PR. The contact hole HLt has a configuration that becomes the contact C3 later.

As shown in FIG. 8B, the insulating layers 56 and 57 that respectively cover the side walls of the contact holes HLc and HLt are formed. For convenience of description, the insulating layers 56 and 57 are given different reference numerals, respectively, but the insulating layers 56 to 57 may be collectively formed in the contact holes HLc and HLt.

In addition, the conductive layers 26 and 27 such as a tungsten layer respectively fill the voids of the contact holes HLc and HLt remaining on the inside of each of the insulating layers 56 and 57. For convenience of description, the conductive layers 26 and 27 are given different reference numerals, respectively, but the conductive layers 26 to 27 may be collectively formed in the contact holes HLc and HLt. As described above, the contact CC and the contact C3 are formed.

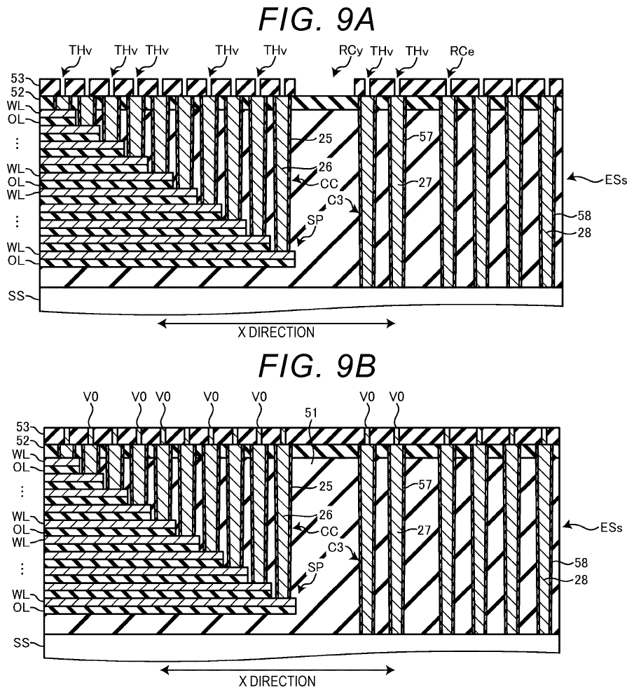

Next, a state where the plug V0 connected to each of the contact C3 and the contact CC is formed is shown in FIGS. 9A and 9B. FIGS. 9A and 9B show cross sections of the staircase region SR, the peripheral region PR, and the outer peripheral region 12a during manufacturing along the X direction.

As shown in FIG. 9A, an insulating layer 53 is formed on the insulating layer 52. Next, a plurality of through-holes THv that penetrate the insulating layer 53 and reach the upper surfaces of each of the plurality of contacts CC and the contact C3, and a recess portion RCe that penetrates the insulating layer 53 and reaches the upper surface of the edge seal ESs are formed.

As shown in FIG. 9B, the plurality of plugs V0 that fill the through-holes THv with a tungsten layer or the like and are respectively connected to the conductive layers 26 and 27 of the plurality of contacts CC and C3, are formed. At this time, the recess portion RCe is also filled with a tungsten layer or the like, and the upper surface of the edge seal ESs, which is a part of the edge seal ESm, extends to the upper surface of the insulating layer 53.

Thereafter, the insulating layer 54 is further formed on the insulating layer 53, and the bit line BL, the wiring layers MX, M0, M1, M2, . . . , the plugs CH, V0, V1, V2, . . . , the electrode pads PDm, and the like are subsequently formed. These insulating layers 51 to 54 constitute a part of the insulating layer 50 in FIGS. 1A and 1B. At this time, a configuration corresponding to these wiring layers, plugs, and the like is also formed on the upper surface of the edge seal ESs, and the edge seal ESm that reaches substantially the same height position as the wiring layers and plugs associated with the stacked body LM is formed.

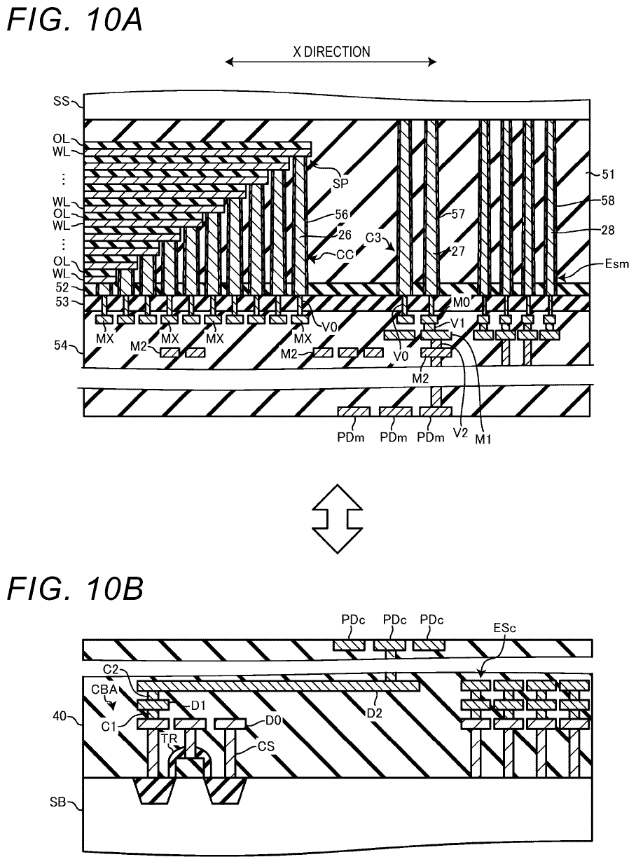

Next, a state where the supporting substrate SS on which the stacked body LM and the like are formed and the semiconductor substrate SB on which the peripheral circuit CBA and the like are formed are bonded to each other is shown in FIGS. 10A and 10B. FIGS. 10A and 10B show a cross section of the supporting substrate SS on which the stacked body LM and the like are formed and the semiconductor substrate SB on which the peripheral circuit CBA and the like are formed, along the X direction.

As shown in FIG. 10B, the peripheral circuit CBA including the transistor TR is formed on the semiconductor substrate SB separate from the supporting substrate SS. In addition, the wiring layer D0, D1, D2, . . . , the contact CS, the vias C1, C2, . . . , the electrode pads PDC, and the like are subsequently formed on the semiconductor substrate SB while forming the insulating layer 40 covering the peripheral circuit CBA.

As shown in FIGS. 10A and 10B, the various configurations are formed in the stacked body LM, and the surface on which the electrode pads PDm of the supporting substrate SS, on which the bit lines BL, the wiring layers MX, M0, M1, M2, . . . the plugs CH, V0, V1, V2, . . . , the electrode pads PDm and the like are formed, are formed faces the surface of the semiconductor substrate SB on which the electrode pads PDc are formed.

In addition, the insulating layer 54 on the supporting substrate SS side is bonded to the insulating layer 40 on the semiconductor substrate SB side. The insulating layers 54 and 40 may be bonded to each other by, for example, being activated by plasma processing or the like before the bonding process. In addition, when the insulating layers 54 and 40 are bonded to each other, the position alignment of the supporting substrate SS and the semiconductor substrate SB is performed such that the electrode pad PDm formed on the insulating layer 54 and the electrode pad PDc formed on the insulating layer 40 overlap each other.

After the insulating layers 54 and 40 are bonded to each other, the electrode pads PDm and PDc are bonded to each other by performing an annealing processing. Thereby, the supporting substrate SS and the semiconductor substrate SB are bonded to each other.

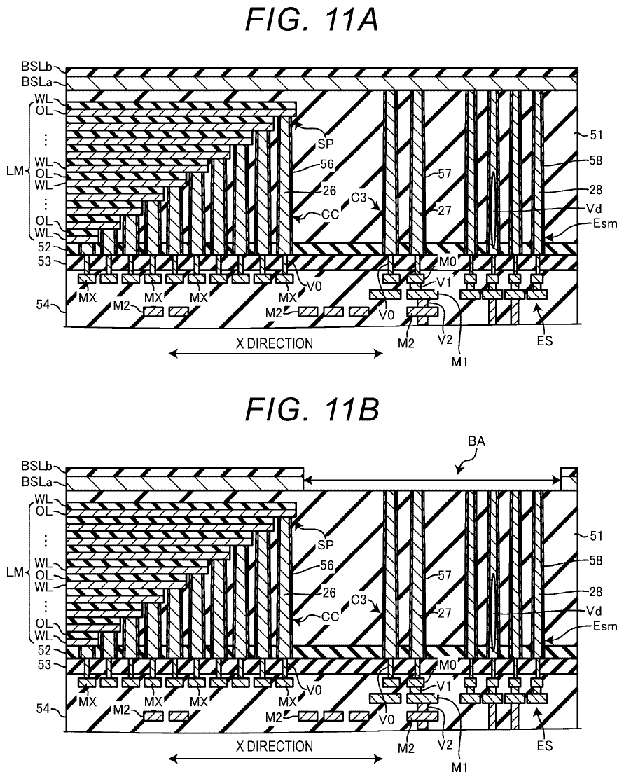

Next, a state until the pad portion PD for supplying an external power to the semiconductor memory device 1 is formed is shown in FIGS. 11A to 13. FIGS. 11A to 13 show cross sections of the staircase region SR, the peripheral region PR, and the outer peripheral region 12a during manufacturing along the X direction, as in FIGS. 10A and 10B described above.

First, a state where the source-side wiring layer BSL is formed above the stacked body LM is shown in FIGS. 11A and 11B. In the steps after FIGS. 11A and 11B, various types of processing are performed on the supporting substrate SS side surface as the processing surface in a state where the supporting substrate SS (refer to FIGS. 10A and 10B) side faces upward.

Prior to the processing in FIG. 11A, the entire upper supporting substrate SS of the stacked body LM and a part of the insulating layer 51 are removed by chemical mechanical polishing (CMP) or the like, and the upper surfaces of the contact C3 and the edge seal ESm are exposed.

As shown in FIG. 11A, the source line layer BSLa and the insulating layer BSLb are stacked in this order on the insulating layer 51 from which the upper surfaces of the contact C3 and the edge seal ESm are exposed.

Next, a mask pattern (not shown) in which a part corresponding to the region BA is opened is formed on the insulating layer BSLb. The insulating layer BSLb and the source line layer BSLa are subsequently etched using a mask pattern. After the insulating layer BSLb and the source line layer BSLa are removed from the region BA, the mask pattern is removed. As a result, a plurality of source-side wiring layers BSL are dispersed on the insulating layer 51.

As described above, a void Vd that extends in the stacking direction may be formed in the conductive layer 28 of the edge seal ESm. The void Vd may expand in the X direction by various types of heat processing in the steps after FIGS. 11a and 11b. Then, as the void Vd expands, the insulating layer 51 in the vicinity of the edge seal ESm may also be compressed in the X direction, and stress may be applied to each layer above the insulating layer 51. As described above, by removing the source-side wiring layer BSL in the vicinity of the edge seal ESm, the source-side wiring layer BSL is prevented from being peeled off from the insulating layer 51, for example, due to the influence of stress from the insulating layer 51. The void Vd is an example of a void.

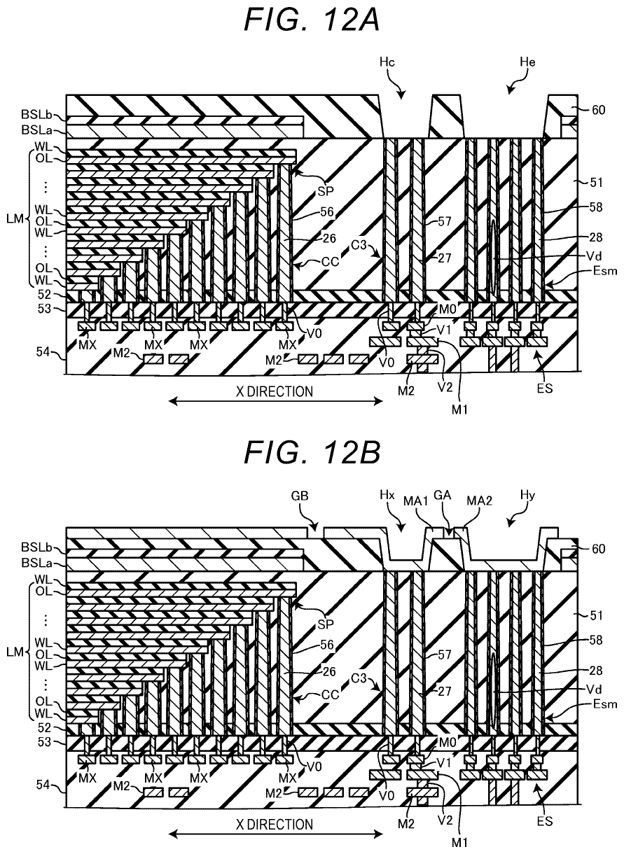

Next, a state where the electrode layers MA1 and MA2 are formed above the plurality of source-side wiring layers BSL is shown in FIGS. 12A and 12B.

First, the insulating layer 60 that covers the entire upper surface of the insulating layer 51 on which the source-side wiring layer BSL is formed is formed. Next, as shown in FIG. 12A, a recess portion Hc that penetrates the insulating layer 60 and reaches the upper surface of the contact C3 is formed in the region BA, and similarly, a recess portion He that penetrates the insulating layer 60 and reaches the upper surface of the edge seal ESm is formed in the region BA.

An aluminum layer that becomes the electrode layer MA later is formed on the upper surface of the insulating layer 60 and the side walls and the bottom surfaces of the recess portions Hc and He. The aluminum layer is formed by, for example, an evaporation method or the like.

Next, a mask pattern (not shown) having a pattern of the electrode layers MA1 and MA2 is formed. In addition, the aluminum layer is etched using the mask pattern until the insulating layer 60 is exposed. Thereby, the electrode layers MA1 and MA2 are formed. The electrode layers MA1 and MA2 are electrically separated from each other by having a gap GA or the like at a part thereof, also have a gap GB in the electrode layer MA1, and are formed in a predetermined pattern. After the electrode layers MA1 and MA2 are formed, the mask pattern is removed. The electrode layers MA1 and MA2 each have recess portions Hx and Hy at positions where the recess portions Hc and He are formed. Thereby, the electrode layer MA1 is connected to the contact C3, and the electrode layer MA2 is connected to the edge seal ESm.

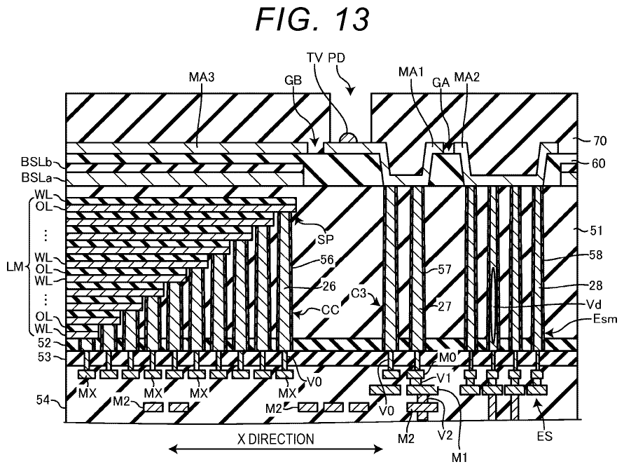

Next, a state where the pad portion PD is formed on the electrode layer MA is shown in FIG. 13.

First, the recess portions Hx and Hy are filled, and the insulating layer 70 that covers the entire upper surface of the insulating layer 60 is formed. Next, as shown in FIG. 13, a recess portion that penetrates the insulating layer 70 above the electrode layer MA1 and reaches the upper surface of the electrode layer MA is formed, and the bonding TV is formed on the bottom surface of the recess portion, which is an exposed part of the electrode layer MA. In this manner, the pad portion PD is formed.

The semiconductor memory device 1 of the embodiment is manufactured as described above.

### Comparative Example

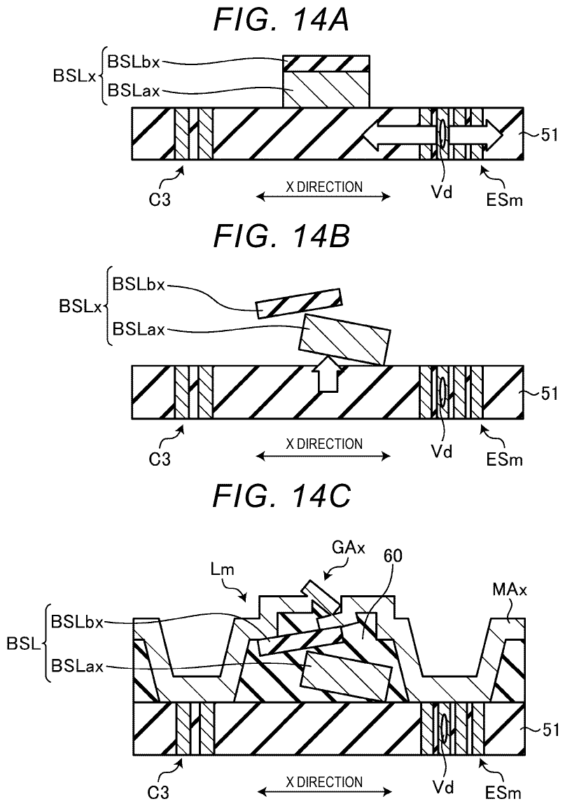

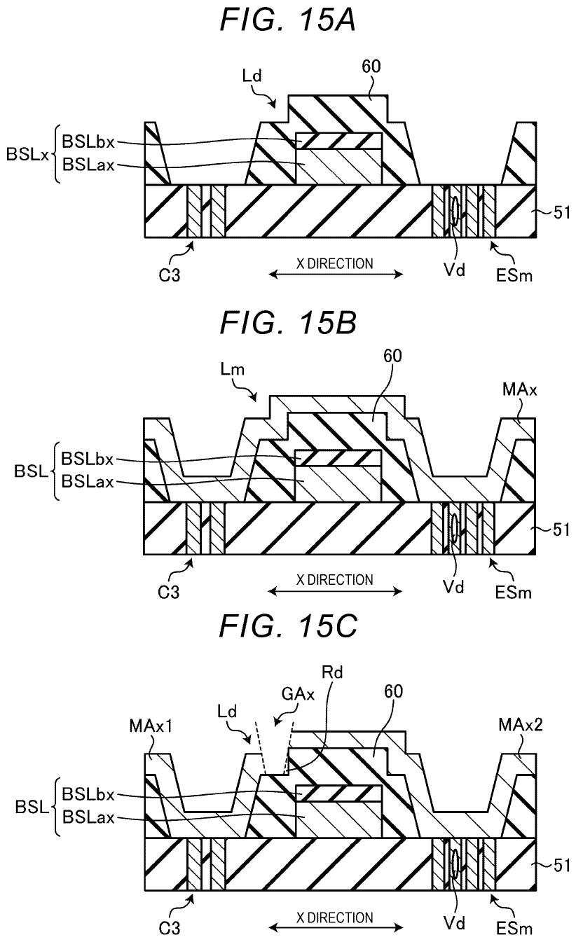

FIGS. 14A to 15C are views showing a semiconductor memory device according to a comparative example. More specifically, FIGS. 14A to 14C and FIGS. 15A to 15C are enlarged cross-sectional views along the X direction showing a part of the processing of forming an electrode layer MAx. FIGS. 14A to 15C respectively show some of the adverse effects that may be caused by a source-side wiring layer BSLx in the semiconductor memory device of the comparative example.

As shown in FIG. 14A, in the manufacturing step of the semiconductor memory device of the comparative example, when the source-side wiring layer BSLx is removed from the pad region and the edge seal region and is etched into a predetermined pattern, for example, the source-side wiring layer BSLx is not removed and remains in a region between the pad region having the contact C3 and the edge seal region having the edge seal ESm.

As described above, the void Vd may be formed during the process of forming the edge seal ESm, and the void Vd may expand in the X direction by various types of heat processing. In this case, the insulating layer 51 in the vicinity of the edge seal ESm may also be compressed in the X direction as the void Vd expands. Compression of the insulating layer 51 in the X direction may cause stress to be applied to each layer above the insulating layer 51. As a result, as shown in FIG. 14B, the source-side wiring layer BSLx may be peeled off from the insulating layer 51.

When the insulating layer 60 and the electrode layer MAx are attempted to be formed on the source-side wiring layer BSLx, as shown in FIG. 14C, the normal formation of the insulating layer 60 and the electrode layer MAx may be hindered by the source line layer BSLax peeled off from the insulating layer 51, the insulating layer BSLbx, and the like, and, for example, the MA1x and the MA2x may be conductive across a gap GAx and the like. As a result, a short circuit may occur between the contact C3 and the edge seal ESm.

Meanwhile, in order to prevent the void Vd from expanding, a technique has been proposed in which a crosslinking film that connects the insulating layers 51 on both sides of the edge seal ESm in the X direction is provided at the lower end portion of the edge seal ESm. As a result, the expansion of the void Vd can be prevented, but the short circuit between the contact C3 and the edge seal ESm is not completely avoided.

In addition, as shown in FIG. 15A, when the source-side wiring layer BSLx is formed on the upper surface of the insulating layer 51 between the pad region and the edge seal region, the insulating layer 60 covering the source-side wiring layer BSLx may be raised by the height of the source-side wiring layer BSLx and a step Ld recessed in the stacking direction may be formed at the shoulder part of the insulating layer 60. When the electrode layer MAx is formed on the upper surface of the insulating layer 60 having such a step Ld, as shown in FIG. 15B, a step Im is also formed at a part of the electrode layer MAx covering the step Ld.

For example, as shown in FIG. 15C, when the gap GAx between the electrode layer MAx and electrode layers MAx1 and MAx2 is formed in such a step Lm, a residue Rd of the electrode layer MAx may remain in the step Lm. Such a residue Rd may cause a short circuit between the electrode layer MAx1 and the electrode layer MAx2.

According to the embodiment, the semiconductor memory device includes the plurality of source-side wiring layers BSL dispersed above the stacked body LM; the electrode layer MA provided above the source-side wiring layers BSL and connected to the upper portions of the contact C3 and the edge seal ESm respectively in the region BA between the plurality of source-side wiring layers BSL; and a pad portion provided above the electrode layer MA for supplying external power to the contact C3 and the edge seal ESm via the electrode layer MA. The pad portion PD and the contact C3 are provided in the element region 11, and the edge seal ESm is provided in the outer peripheral region 12a. The element region 11 and the outer peripheral region 12a are in contact with each other without the source-side wiring layer BSL interposed therebetween.

As described above, since the source-side wiring layer BSL is not formed in the region BA, the peeling of the source-side wiring layer BSL does not occur, and thus the defective formation of the electrode layer MA1 and the electrode layer MA2 can be prevented. As a result, a short circuit between the electrode layer MA1 and the electrode layer MA2 can be reduced.

In addition, since the layer thickness of the insulating layer 60 in the region BA can be made uniform, the gap GA can be formed more reliably without the residue Rd. As a result, it is possible to more reliably prevent a short circuit between the electrode layer MA1 and the electrode layer MA2.

In the above-described embodiment, after the semiconductor substrate SB is bonded, the source-side wiring layer BSL is formed on the stacked body LM by the rear surface process. However, the source-side wiring layer may be formed in a process on the supporting substrate SS. In this case, the conductive polysilicon layer or the like that becomes the source-side wiring layer BSL can be formed on the supporting substrate SS, and then the stacked body LMs and the like can be subsequently formed. Thereafter, the semiconductor substrate SB is bonded, and the conductive polysilicon layer is processed into a pattern of the source-side wiring layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of first conductive layers and a plurality of insulating layers alternately stacked in a first direction;
a second conductive layer extending in the first direction and disposed outside the stacked body;
a third conductive layer extending in the first direction and surrounding the stacked body when viewed in the first direction;
a first wiring layer provided above the stacked body and extending in a second direction that intersects the first direction;
a second wiring layer provided above the stacked body and provided apart from the first wiring layer in the second direction;
an electrode layer provided above the first wiring layer and the second wiring layer, and connected to each of upper portions of the second conductive layer and the third conductive layer between the first wiring layer and the second wiring layer; and
a pad portion provided in the electrode layer and configured to supply external power to the second conductive layer and the third conductive layer via the electrode layer, wherein
a first region, including the first wiring layer, the pad portion, and the second conductive layer, and a second region, including the second wiring layer and the third conductive layer, are adjacent to each other in the second direction.

2. The semiconductor memory device according to claim 1, further comprising:
a semiconductor layer penetrating the stacked body in the first direction and connected to a part of the first wiring layer.

3. The semiconductor memory device according to claim 2, wherein
the electrode layer includes a first electrode layer provided in the first region and a second electrode layer provided in the second region, and the first electrode layer and the second electrode layer are separated from each other.

4. The semiconductor memory device according to claim 1, wherein
the third conductive layer has a void extending in an upside-down direction of the stacked body.

5. The semiconductor memory device according to claim 1, further comprising:
a plurality of transistors provided below the stacked body and electrically connected to the electrode layer via the third conductive layer.

6. A semiconductor memory device comprising:
a first region that includes a stacked body with a plurality of first conductive layers and a plurality of first insulating layers alternately stacked in a first direction, and a second conductive layer extending in the first direction;
a second region provided adjacent to the first region in a second direction that intersects the first direction, and including a third conductive layer that extends in the first direction;
a first wiring layer provided above the stacked body;
a first electrode layer that includes a first portion and a second portion provided above the first wiring layer, and a third portion provided between the first portion and the second portion, positioned below the first portion and the second portion, and connected to the second conductive layer;
a second electrode layer that includes a fourth portion and a fifth portion provided above the first wiring layer, and a sixth portion provided between the fourth portion and the fifth portion, positioned below the fourth portion and the fifth portion, and connected to the third conductive layer; and
a second insulating layer provided between the second portion and the fourth portion.

7. The semiconductor memory device according to claim 6, wherein
the first portion is a pad portion including bonding.

8. The semiconductor memory device according to claim 6, wherein
the third portion and the sixth portion are positioned above a first conductive layer positioned at an uppermost position among the plurality of first conductive layers.

9. The semiconductor memory device according to claim 6, further comprising:
a fourth region facing the second region in the second direction via the first region, including a fourth conductive layer that extends in the first direction, and connected to the third conductive layer.

10. The semiconductor memory device according to claim 6, further comprising:
a semiconductor layer penetrating the stacked body and extending in the first direction; and
a memory layer part provided between the semiconductor layer and the first conductive layer.

11. The semiconductor memory device according to claim 6, wherein
the third conductive layer has a void that extends in the first direction.

12. The semiconductor memory device according to claim 6, further comprising:
a plurality of transistors provided below the stacked body and electrically connected to the second electrode layer via the third conductive layer.

13. The semiconductor memory device according to claim 6, wherein
the second insulating layer is provided above the first wiring layer.

14. The semiconductor memory device according to claim 6, further comprising:
a second wiring layer provided apart from the first wiring layer in the second direction, wherein
the first electrode layer and the second electrode layer are provided between the first wiring layer and the second wiring layer.
